(19) United States
(12) Patent Application Publication
(10) Pub. No.: US 2024/0347648 A1
(43) Pub. Date: Oct. 17, 2024

(54) PACKAGE STRUCTURE AND PACKAGING METHOD

(71) Applicant: JCET Group Co. Ltd., Wuxi (CN)

(72) Inventors: Xianfang YANG, Wuxi (CN); Peng LI, Wuxi (CN); Hengli TANG, Wuxi (CN); Junjun LI, Wuxi (CN)

(73) Assignee: JCET Group Co. Ltd., Wuxi (CN)

(21) Appl. No.: 18/609,742

(22) Filed: Mar. 19, 2024

(30) Foreign Application Priority Data
Apr. 17, 2023 (CN) 202310414228.4

(51) Int. Cl. H01L 31/0203; H01L 23/00

(52) U.S. Cl. CPC H01L 31/0203; H01L 24/32; H01L 24/48; H01L 24/73; H01L 24/33; H01L 2224/32225; H01L 2224/33181; H01L 2224/48091; H01L 2224/48227; H01L 2224/73215; H01L 2224/73265

(57) ABSTRACT

The present disclosure provides a package structure and a packaging method. The method includes: providing a substrate, a sensor chip electrically connected to the substrate is arranged on a surface of the substrate, a light-receiving region being arranged on a surface, facing away from the substrate, of the sensor chip; arranging a transparent cover plate on the sensor chip, the transparent cover plate covers the light-receiving region, and a separator film is arranged on a side, facing away from the sensor chip, of the transparent cover plate; performing molding to form a molding layer, the molding layer wraps the sensor chip, the transparent cover plate, and the separator film; thinning the molding layer from a side, facing away from the substrate, of the molding layer to form a molding body, the molding body exposes the separator film; and removing the separator film to expose the transparent cover plate.

### CROSS-REFERENCE TO RELATED APPLICATIONS

This application is based upon and claims priority to Chinese Patent Application No. 202310414228.4, filed on Apr. 17, 2023, the entire content of which is incorporated herein by reference for all purposes.

### TECHNICAL FIELD

The present disclosure relates to the technical field of semiconductor packaging, and in particular, relates to a package structure and a packaging method.

### BACKGROUND

Optical sensors conduct measurements in accordance with optical principles, and have such characteristics as non-contact and non-destructive measurements, almost no interference, high-speed transmission, remote measurability, and remote controllability. The optical sensors are widely used in aerospace, aviation, national defense research, information industry, machinery, power, energy, transportation, biology, medicine, and the like fields. At present, the optical sensors mainly include: an optical image sensor, a transmission-type optical sensor, an optical measurement sensor, an optical mouse sensor, a reflection-type optical sensor, and the like.

As for packaging of a conventional optical sensor, electrical connection is implemented typically by wire bonding, then light transmission and sealing protection are achieved for a sensor chip by mounting a transparent cover plate above the sensor chip, and finally the chip is packaged with a molding material. However, in the packaging process, the transparent cover plate is easily contaminated by overflow of a molding material, which affects the sensitivity of the optical sensor. In addition, the transparent cover plate may be damaged due to an excessive clamping force, and consequently the reliability of the package structure of the optical sensor is affected.

Therefore, providing a new package structure and a packaging method therefor becomes the focus of current research.

### SUMMARY

A technical problem to be solved by the present disclosure is to provide a new package structure and a packaging method.

In one aspect, the present disclosure provides a packaging method. The packaging method includes:
providing a substrate, wherein a sensor chip electrically connected to the substrate is arranged on a surface of the substrate, a light-receiving region being arranged on a surface, facing away from the substrate, of the sensor chip;
arranging a transparent cover plate on the sensor chip, wherein the transparent cover plate covers the light-receiving region, and a separator film is arranged on a side, facing away from the sensor chip, of the transparent cover plate;
performing molding to form a molding layer, wherein the molding layer wraps the sensor chip, the transparent cover plate, and the separator film;
thinning the molding layer from a side, facing away from the substrate, of the molding layer to form a molding body, wherein the molding body exposes the separator film; and
removing the separator film to expose the transparent cover plate.

In some embodiments, prior to arranging the transparent cover plate on the sensor chip, the method includes:
forming the separator film on a surface of the transparent cover plate; and
in the step of arranging the transparent cover plate on the sensor chip, attaching a surface, facing away from the separator film, of the transparent cover plate onto the sensor chip.

In some embodiments, arranging the transparent cover plate on the sensor chip includes:
arranging the transparent cover plate on the sensor chip; and
attaching the separator film onto a surface, facing away from the sensor chip, of the transparent cover plate.

In some embodiments, arranging the transparent cover plate on the sensor chip includes:

securing the transparent cover plate onto the sensor chip by an adhesive layer, wherein the adhesive layer is a transparent layer.

In some embodiments, thinning the molding layer from the side, facing away from the substrate, of the molding layer comprises:
coarse grinding the molding layer to thin the molding layer having a predetermined thickness; and
fine grinding the molding layer until the separator film is exposed.

In some embodiments, in the step of molding to form the molding body, a distance from the separator film to an upper surface of the molding layer is greater than a predetermined value.

In some embodiments, a conductive pad is further arranged on the surface, facing away from the substrate, of the sensor chip, and the sensor chip is arranged on the surface of the substrate by:
attaching the sensor chip onto the surface of the substrate; and
electrically connecting the conductive pad to the substrate by a conductive wire.

In another aspect, the present disclosure further provides a package structure. The package structure includes:
a substrate;
a sensor chip, arranged on the substrate and electrically connected to the substrate, wherein a light-receiving region is arranged on a surface, facing away from the substrate, of the sensor chip;
a transparent cover plate, arranged on the sensor chip and covering the light-receiving region; and
a molding body, covering the substrate and an uncovered surface of the sensor chip, and wrapping a side surface of the transparent cover plate, wherein in a direction perpendicular to the substrate, a surface of the transparent cover plate is lower than an upper surface of the molding body.

In some embodiments, the transparent cover plate is secured onto the sensor chip by an adhesive layer, wherein the adhesive layer is a transparent layer.

In the packaging method according to the embodiments of the present disclosure, the molding layer covers the surface of the transparent cover plate, and the separator film separates the molding layer from the transparent cover plate to avoid contact between the molding layer and the surface, where light needs to be incident, of the transparent cover plate; and where the molding layer is thinned and the separator film is removed, the transparent cover plate is exposed to form a package structure. In the molding process of the packaging method according to the present disclosure, the transparent cover plate does not need to be in contact with the upper surface of a molding cavity of a molding mold, the impact exerted by the force of the molding mold to the transparent cover plate is avoided, the effective transparent region of the transparent cover plate is controlled, and the rupture of the transparent cover plate due to an excessive force is prevented, such that the stability and yield of the package structure are greatly improved.

### BRIEF DESCRIPTION OF THE DRAWINGS

For a clearer description of the technical solutions according to the embodiments of the present disclosure, hereinafter brief description is given with reference to the accompanying drawings for illustrating the embodiments. Apparently, the accompanying drawings described hereinafter only illustrate some embodiments of the present disclosure, and other accompanying drawings may also be derived by persons of ordinary skill in the art based on these accompanying drawings without any creative effort.

FIG. 1 is a schematic diagram of a conventional molding process;

FIG. 2 is a schematic flowchart of steps of a packaging method according to some embodiments of the present disclosure;

FIG. 3A is a schematic diagram of a structure obtained by step S10 of a packaging method according to some embodiments of the present disclosure;

FIG. 3B is a schematic diagram of a structure obtained by step S11 of a packaging method according to some embodiments of the present disclosure;

FIG. 3C is a schematic diagram of a structure acquired by step S12 of a packaging method according to some embodiments of the present disclosure;

FIGS. 3D and 3E are schematic diagrams of a structure acquired by step S13 of a packaging method according to some embodiments of the present disclosure; and

FIG. 3F is a schematic diagram of a structure acquired by step S14 of a packaging method according to some embodiments of the present disclosure.

### DETAILED DESCRIPTION

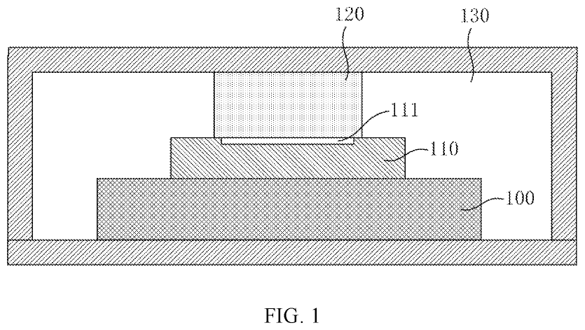

As described in the background, as for packaging of a conventional optical sensor, electrical connection is implemented typically by wire bonding, then light transmission and sealing protection are achieved for a sensor chip by mounting a transparent cover plate above the sensor chip, and finally the chip is packaged with a molding material. Specifically, referring to FIG. 1, FIG. 1 is a schematic diagram of a conventional molding process. A sensor chip 110 is arranged on a substrate 100. A light-receiving region 111 is arranged on a surface, facing away from the substrate 100, of the sensor chip 110. A transparent cover plate 120 is arranged on the sensor chip 110. The transparent cover plate 120 covers the light-receiving region 111. During the molding process, the substrate 100, the sensor chip 110, and the transparent cover plate 120 are disposed in a molding cavity 130 of a molding mold, and then a molding material into the molding cavity 130 to implement molding and form a package structure. To expose the transparent cover plate 120 out of the package structure, a surface, facing away from the sensor chip 110, of the transparent cover plate 120 is attached to an upper surface of the molding cavity 130 by virtue of a force applied by the molding mold, such that the molding material is prevented from spreading to the surface of the transparent cover plate 120 during molding.

However, the force applied by the molding mold is hard to control. Where the force is excessively small, the upper surface of the molding cavity 130 may fail to be fully attached to the transparent cover plate 120, and the molding material may spread to an edge or interior of the transparent cover plate 120, such that an effective transparent region fails to be precisely controlled, and even the flexibility of the package structure is affected. Where the force is excessively large, the transparent cover plate 120 may fail to withstand the force and rupture, and thus the yield and quality of the package structure are affected.

Accordingly, some embodiments of the present disclosure provide a package structure and a packaging method. With these technical solutions, the impact exerted by the force of the molding mold to the transparent cover plate is avoided, the effective transparent region is controlled, and the rupture of the transparent cover plate due to an excessive force is prevented, such that the stability and yield of the package structure are greatly improved.

The technical solutions of the embodiments of the present disclosure are clearly and thoroughly described hereinafter with reference to the accompanying drawings. Obviously, the embodiments described herein are merely exemplary ones, but are not all the embodiments. Based on the embodiments of the present invention, all other embodiments derived by persons of ordinary skill in the art without any creative efforts shall fall within the protection scope of the present invention.

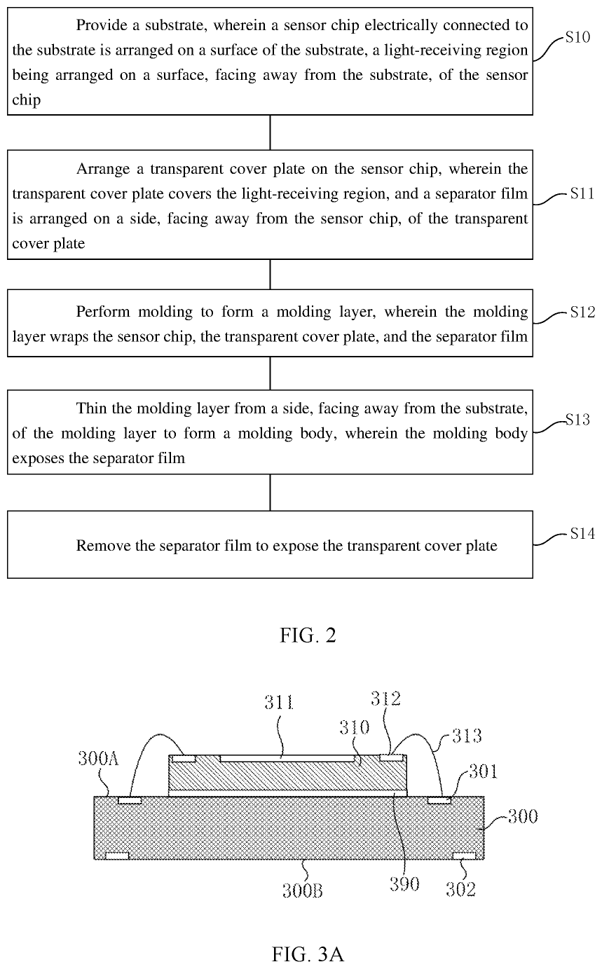

FIG. 2 is a schematic flowchart of steps of a packaging method according to some embodiments of the present disclosure. Referring to FIG. 2, the packaging method includes: step S10, providing a substrate 300, wherein a sensor chip 310 electrically connected to the substrate 300 is arranged on a surface of the substrate 300, a light-receiving region 311 being arranged on a surface, facing away from the substrate 300, of the sensor chip 310; step S11, arranging a transparent cover plate 320 on the sensor chip 310, wherein the transparent cover plate 320 covers the light-receiving region 311, and a separator film 330 is arranged on a side, facing away from the sensor chip 310, of the transparent cover plate 320; step S12, performing molding to form a molding layer 340, wherein the molding layer 340 wraps the sensor chip 310, the transparent cover plate 320, and the separator film 330; step S13, thinning the molding layer 340 from a side, facing away from the substrate 300, of the molding layer 340 to form a molding body 350, wherein the molding body 350 exposes the separator film 330; and step S14, removing the separator film 330 to expose the transparent cover plate 320.

In the packaging method according to the embodiments of the present disclosure, the molding layer 340 covers the surface of the transparent cover plate 320, and the separator film 330 separates the molding layer 340 from the transparent cover plate 320 to avoid contact between the molding layer 340 and the surface, where light needs to be incident, of the transparent cover plate 320; the molding layer 340 is thinned and the separator film 330 is removed, such that the transparent cover plate 320 is exposed. In the molding process, the transparent cover plate 320 does not need to be in contact with the upper surface of the molding cavity of the molding mold, the impact exerted by the force of the molding mold to the transparent cover plate 320 is avoided, the effective transparent region of the transparent cover plate 320 is controlled, and the rupture of the transparent cover plate 320 due to an excessive force is prevented, such that the stability and yield of the package structure are greatly improved.

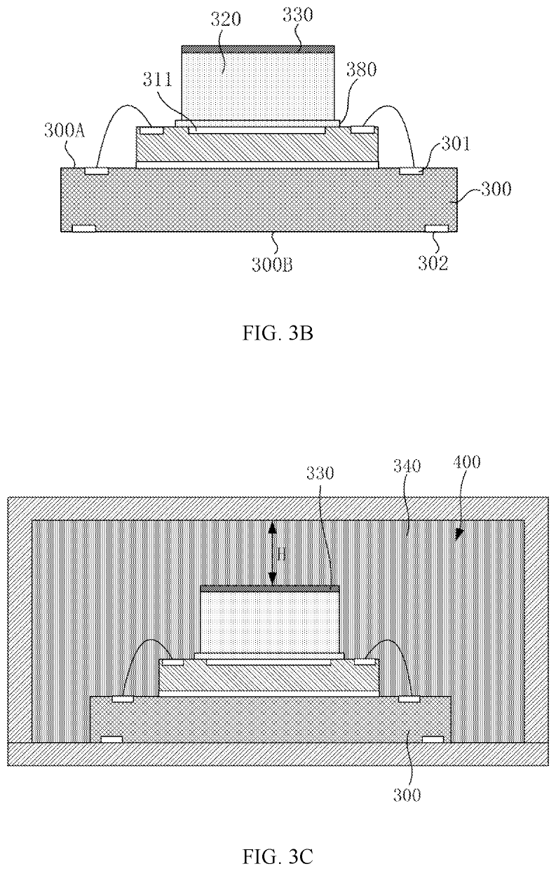

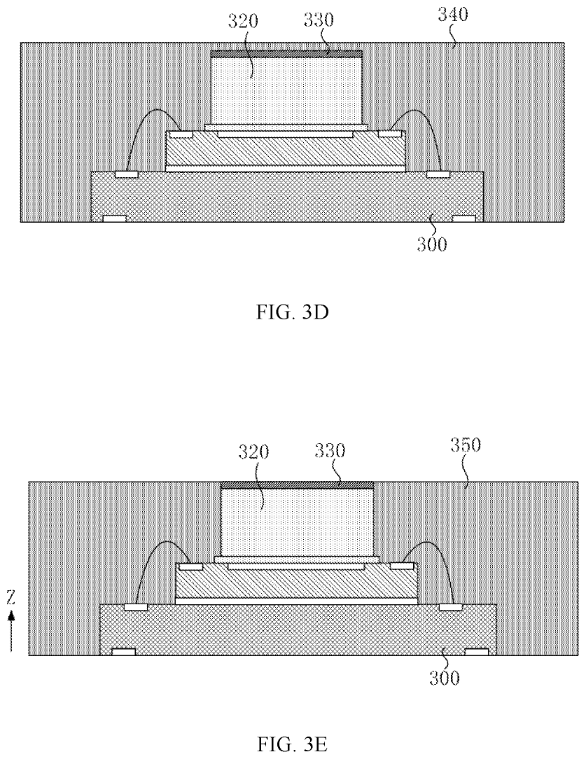

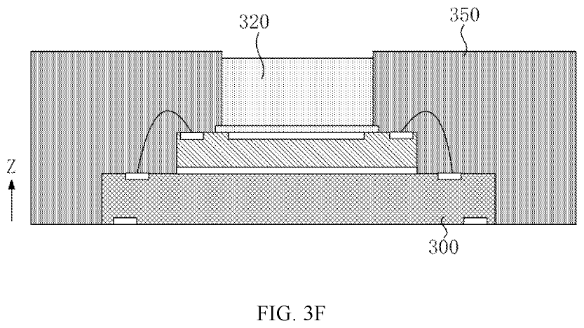

FIG. 3A to FIG. 3F illustrate process flowcharts of a packaging method according to some embodiments of the present disclosure.

Referring to FIG. 2 and FIG. 3A, in step S10, a substrate 300 is provided. A sensor chip 310 electrically connected to the substrate 300 is arranged on a surface of the substrate 300. A light-receiving region 311 is arranged on a surface, facing away from the substrate 300, of the sensor chip 310.

The substrate 300 has an upper surface 300A and a lower surface 300B. The upper surface 300A and the lower surface 300B are opposite to each other. The sensor chip 310 is arranged on the upper surface 300A of the substrate 300.

The substrate 300 is configured to support the sensor chip 310 and electrically connect the sensor chip 310 to an external circuit board. The substrate 300 includes, but is not limited to any one of a silicon substrate, a glass substrate, a metal substrate, a semiconductor substrate, a polymer substrate, and a ceramic substrate. A conductive interconnect structure is arranged in the substrate 300, and the sensor chip 310 is electrically connected to the external circuit board via the conductive interconnect structure.

As illustrated in FIG. 3A, a first conductive pad 301 is arranged on the upper surface 300A of the substrate 300, and a second conductive pad 302 is arranged on the lower surface 300B of the substrate 300. The first conductive pad 301 and the second conductive pad 302 are electrically connected via the conductive interconnect structure in the substrate 300. The second conductive pad 302 may be configured to be electrically connected to the external circuit board.

The sensor chip 310 is an optical sensor chip, and is configured to receive light and implement photoelectric conversion. In some embodiments, the sensor chip 310 includes, but is not limited to, a silicon photonics ship. A light-receiving region 311 configured to receive light is arranged on a surface, facing away from the substrate 300, of the sensor chip 310.

The sensor chip 310 is attached to the upper surface 300A of the substrate 300, and a third conductive pad 312 is arranged on the surface, facing away from the substrate 300, of the sensor chip. The third conductive pad 312 is electrically connected to the first conductive pad 301 on the substrate 300 via a conductive wire 313, and hence the sensor chip 310 is electrically connected to the external circuit board.

As an example, some embodiments of the present disclosure provide a method for arranging the sensor chip 310 on the surface of the substrate 300. The method includes: attaching the sensor chip 310 to the surface of the substrate 300, for example, attaching the sensor chip 310 to the upper surface 300A of the substrate 300; and electrically connecting the third conductive pad 312 to the first conductive pad 301 on the substrate 300 via the conductive wire 313. The way of electrically connecting the third conductive pad 312 to the first conductive pad 301 on the substrate 300 via the conductive wire 313 includes, but is not limited to wire bonding.

In some embodiments, the sensor chip 310 is attached to the upper surface 300A of the substrate 300 via a die attach film (DAF) 390. In some other embodiments, the sensor chip 310 may also be secured to the upper surface 300A of the substrate 300 via other adhesive materials.

Referring to FIG. 2 and FIG. 3B, in step S11, a transparent cover plate 320 is arranged over the sensor chip 310. The transparent cover plate 320 covers the light-receiving region 311, and a separator film 330 is arranged on a side, facing away from the sensor chip 310, of the transparent cover plate 320.

The transparent cover plate 320 allows ambient light to be incident onto the light-receiving region 311 of the sensor chip 310, and the transparent cover plate 320 includes, but is not limited to a glass plate. In some embodiments, the transparent cover plate 320 is secured to the sensor chip 310 via a bonding layer 380. The bonding layer 380 is a transparent layer. The bonding layer 380 may not block the external light from being incident onto the light-receiving region 311. In some embodiments, the bonding layer 380 includes, but is not limited to, a die attach film (DAF).

As an example, some embodiments of the present disclosure provide a method for arranging the transparent cover plate 320 on the sensor chip 310. The method includes: forming a bonding material layer on the surface, facing away from the substrate 300, of the sensor chip 310; patterning the bonding material layer, and maintaining a region of the bonding material layer for arranging the transparent cover plate 320 as the bonding layer 380; and attaching the transparent cover plate 320 to the bonding layer 380 to secure the transparent cover plate 320. In some other embodiments, the transparent cover plate 320 is arranged on the bonding material layer first, and then the region of the bonding material layer where the transparent cover plate 320 is not arranged is removed.

The separator film 330 is arranged on a surface, facing away from the sensor chip 310, of the transparent cover plate 320, that is, the separator film 330 is arranged on a surface, where light needs to be incident, of the transparent cover plate 320, as a protective layer of the transparent cover plate 320. In this way, during molding, the molding material is prevented from being in contact with the transparent cover plate 320. In some embodiments, the separator film 330 may be a blue film, a UV film, or the like, which may be secured to the surface of the transparent cover plate 320 in an attachment form.

In some embodiments, prior to or upon arranging the transparent cover plate 320 on the sensor chip 310, the separator film 330 is formed on the transparent cover plate 320.

For example, in some embodiments, the separator film 330 is first formed on the surface of the transparent cover plate 320; and then a surface, facing away from the separator film 330, of the transparent cover plate 320 is attached to the sensor chip 310. This method is less difficult in process, and the separator film 330 may be attached to a large-sized transparent cover plate 320, and then the large-sized transparent cover plate 320 is cut to a small-sized transparent cover plate 320. Therefore, batch production is achieved.

Still for example, in some embodiments, the transparent cover plate 320 not covered by the separator film 330 is arranged on the sensor chip 310; and the separator film 330 is attached to the surface, facing away from the sensor chip 310, of the transparent cover plate 320. This method prevents damages to the separator film 330, and ensures integrity of the separator film 330.

Referring to FIG. 1 and FIG. 3C, in step S12, molding is performed to form a molding layer 340. The molding layer 340 wraps the sensor chip 310, the transparent cover plate 320, and the separator film 330.

In this step, the semiconductor structure is placed into a molding cavity 400 of the molding mold, and the molding material is filled into the molding cavity 400. The molding material fills up the molding cavity 400, and covers an exposed surface of the substrate 300, a side surface of the sensor chip 310, and a surface not covered by the transparent cover plate 320, the side surface of the transparent cover plate 320, and a surface of the separator film 330. The separator film 330 separates the transparent cover plate 320 from the molding material. During execution of the molding process, the surface of the transparent cover plate 320 is not in contact with an upper surface of the molding cavity 400, the molding mold does not need to apply a force to the transparent cover plate 320, such that the situation where the transparent cover plate 320 ruptures due to an excessively large force is avoided.

In some embodiments, a distance H from the separator film 330 to an upper surface of the molding layer 340 is greater than a predetermined value. That is, a distance from the separator film 330 to the upper surface of the molding cavity 400 is greater than a predetermined value. With this configuration, a sufficient space is provided for flow of the molding material, and the situation where the molding material fails to cover the surface of the separator film 330 due to an excessively small space. The predetermined value may be defined according to actual process needs.

Referring to FIG. 1, FIG. 3D, and FIG. 3E, in step S13, the molding layer 340 is thinned from a side, facing away from the substrate 300, of the molding layer 340 to form a molding body 350. The molding body 350 exposes the separator film 330.

In this step, the molding layer 340 may be thinned by a polishing process, and hence the molding body 350 is formed.

The polishing process includes crude polishing, fine polishing, or a combination of crude polishing and fine polishing. In some embodiments, the molding body 350 may be formed by first crude polishing and then fine polishing. For example, referring to FIG. 3D, the molding layer 340 is first subjected to crude polishing to thin the molding layer 340 by a predetermined thickness. Referring to FIG. 3E, the molding layer 340 is then subjected to fine polishing to expose the separator film 330 The crude polishing process is capable of quickly grinding the molding layer 340, and thus processing time is reduced. The fine polishing has a low grinding speed, and thus over-grinding causing damages to the transparent cover plate 320 is prevented, and the surface of the molding body 350 is flat and has no scratch. The crude polishing may employ mechanical polishing or chemical mechanical polishing (CMP). The chemical mechanical polishing may employ a process having a high polishing speed to accelerate grinding of the molding layer 340. The fine polishing may employ chemical mechanical polishing having a low grinding speed to prevent over-grinding causing damages to the transparent cover plate 320, and prevent damages to flatness of the surface of the molding body 350.

Referring to FIG. 1 and FIG. 3F, in step S14, the separator film 330 is removed to expose the transparent cover plate 320. In this step, the separator film 330 is removed by heating, soaking in a stripping solution, or using an external auxiliary device.

In some embodiments, upon formation of the molding body 350, along a direction perpendicular to the substrate 300 (Z direction in FIG. 3E and FIG. 3F), an upper surface of the molding body 350 is flush with the surface of the separator film 330, and in this case, where the separator film 330 is removed, the upper surface of the transparent cover plate 320 is lower than the upper surface of the molding body 350.

In the packaging method according to the embodiments of the present disclosure, the region, which is covered by the separator film 330, of the transparent cover plate 320 is the effective transparent region, such that the effective transparent region of the transparent cover plate 320 is controlled, and the transparent cover plate 320 does not need to be in contact with the upper surface of the molding cavity 400 of the molding mold. In this way, the impact caused by the force applied by the molding mold to the transparent cover plate 320 is prevented, and thus the stability and yield of the package structure are greatly improved.

Some embodiments of the present disclosure further provide a package structure that is formed using the packaging method as described above. Referring to FIG. 3A to FIG. 3F, the package structure includes a substrate 300, a sensor chip 310, a transparent cover plate 320, and a molding body 350. The sensor chip 310 is arranged on the substrate 300 and is electrically connected to the substrate 300, and a light-receiving region 311 is arranged on a surface, facing away from the substrate 300, of the sensor chip 310. The transparent cover plate 320 is arranged on the sensor chip 310, and covers the light-receiving region 311. The molding body 350 covers the substrate 300 and a surface, which is not covered, of the sensor chip 310, and wraps a side face of the transparent cover plate 320; and along the direction perpendicular to the substrate 300, the upper surface of the transparent cover plate 320 is lower than the upper surface of the molding body 350.

The substrate 300 has an upper surface 300A and a lower surface 300B. The upper surface 300A and the lower surface 300B are opposite to each other. The sensor chip 310 is arranged on the upper surface 300A of the substrate 300. The sensor chip 310 is an optical sensor chip 310, and is configured to receive light and implement photoelectric conversion. A light-receiving region 311 configured to receive light is arranged on a surface, facing away from the substrate 300, of the sensor chip 310.

In some embodiments, a first conductive pad 301 is arranged on the upper surface 300A of the substrate 300, and a second conductive pad 302 is arranged on the lower surface 300B of the substrate 300. The first conductive pad 301 and the second conductive pad 302 are electrically connected via the conductive interconnect structure in the substrate 300. The sensor chip 310 is attached to the upper surface 300A of the substrate 300, and a third conductive pad 312 is arranged on the surface, facing away from the substrate 300, of the sensor chip. The third conductive pad 312 is electrically connected to the first conductive pad 301 of the first substrate 300 via a conductive wire 313, and hence the sensor chip 310 is electrically connected to the external circuit board.

The transparent cover plate 320 allows ambient light to be incident onto the light-receiving region 311 of the sensor chip 310, and the transparent cover plate 320 includes, but is not limited to a glass plate. In some embodiments, the transparent cover plate 320 is secured to the sensor chip 310 via a bonding layer 380. The bonding layer 380 is a transparent layer, which may not block the external light from being incident onto the light-receiving region 311. In some embodiments, the bonding layer 380 includes, but is not limited to, a die attach film (DAF).

A material of the molding body 350 includes, but is not limited to epoxy resin. Along the direction perpendicular to the substrate 300 (Z direction in the drawings), due to limitations of the packaging process, the upper surface of the transparent cover plate 320 is lower than the upper surface of the molding body 350.

In the package structure according to the embodiments of the present disclosure, the effective transparent region of the transparent cover plate 320 has a high consistency, and the stability of the package structure is greatly improved.

In addition, terms “comprise,” “include,” and variations thereof used herein in the text of the present disclosure are intended to define a non-exclusive meaning. It should be noted that the terms such as “first,” “second,” and the like in the specifications, claims and the accompanying drawings of the present disclosure are intended to distinguish different objects but are not intended to define a specific order or a definite time sequence. Unless otherwise clearly indicated in the context, it should be understood that the data used in this way can be interchanged under appropriate circumstances. The term “one or more” may be used to describe a feature, structure, or characteristic in the singular, or may be used to describe a feature, structure, or combination of features in the plural, depending at least in part on the context. The term “based on” may be understood as not necessarily intended to express a set of exclusive factors, but may alternatively allow for the presence of other factors not necessarily explicitly described, again depending at least in part on the context. In cases of no conflict, the embodiments and features in the embodiments of the present disclosure may be combined together. Further, in the above description, descriptions of well-known components and techniques are omitted so as not to unnecessarily obscure the inventive concepts of the present disclosure. In various embodiments of the present disclosure, the same or similar parts between the embodiments may be referenced to each other. In each embodiment, the portion that is different from other embodiments is concentrated and described.

Described above are preferred embodiments of the present disclosure. It should be noted that persons of ordinary skill in the art may derive other improvements or polishments without departing from the principles of the present disclosure. Such improvements and polishments shall be deemed as falling within the protection scope of the present disclosure.

What is claimed is:

1. A packaging method, comprising:
providing a substrate, wherein a sensor chip electrically connected to the substrate is arranged on a surface of the substrate, a light-receiving region is arranged on a surface, facing away from the substrate, of the sensor chip;
arranging a transparent cover plate on the sensor chip, wherein the transparent cover plate covers the light-receiving region, and a separator film is arranged on a side, facing away from the sensor chip, of the transparent cover plate;
performing molding to form a molding layer, wherein the molding layer wraps the sensor chip, the transparent cover plate, and the separator film;
thinning the molding layer from a side, facing away from the substrate, of the molding layer to form a molding body, wherein the molding body exposes the separator film; and
removing the separator film to expose the transparent cover plate.

2. The packaging method according to claim 1, wherein prior to arranging the transparent cover plate on the sensor chip, the method comprises:
forming the separator film on a surface of the transparent cover plate; and
wherein arranging the transparent cover plate on the sensor chip comprises attaching a surface, facing away from the separator film, of the transparent cover plate onto the sensor chip.

3. The packaging method according to claim 1, wherein arranging the transparent cover plate on the sensor chip comprises:
arranging the transparent cover plate on the sensor chip; and
attaching the separator film onto a surface, facing away from the sensor chip, of the transparent cover plate.

4. The packaging method according to claim 1, wherein arranging the transparent cover plate on the sensor chip comprises:
securing the transparent cover plate onto the sensor chip by an adhesive layer, wherein the adhesive layer is a transparent layer.

5. The packaging method according to claim 1, wherein thinning the molding layer from the side, facing away from the substrate, of the molding layer comprises:
coarse grinding the molding layer to thin the molding layer having a predetermined thickness; and
fine grinding the molding layer until the separator film is exposed.

6. The packaging method according to claim 1, wherein when molding to form the molding body, a distance from the separator film to an upper surface of the molding layer is greater than a predetermined value.

7. The packaging method according to claim 1, wherein a conductive pad is further arranged on the surface, facing away from the substrate, of the sensor chip, and the sensor chip is arranged on the surface of the substrate by:
attaching the sensor chip onto the surface of the substrate; and
electrically connecting the conductive pad to the substrate by a conductive wire.

8. A package structure, comprising:
a substrate;
a sensor chip, arranged on the substrate and electrically connected to the substrate, wherein a light-receiving region is arranged on a surface, facing away from the substrate, of the sensor chip;
a transparent cover plate, arranged on the sensor chip and covering the light-receiving region; and
a molding body, covering the substrate and an uncovered surface of the sensor chip, and wrapping a side surface of the transparent cover plate, wherein in a direction perpendicular to the substrate, an upper surface of the transparent cover plate is lower than an upper surface of the molding body.

9. The package structure according to claim 8, wherein the transparent cover plate is secured onto the sensor chip by an adhesive layer, wherein the adhesive layer is a transparent layer.
